(19) United States
(12) Patent Application Publication
(10) Pub. No.: US 2024/0304668 A1
(43) Pub. Date: Sep. 12, 2024

(54) SEMICONDUCTOR DEVICE

(71) Applicant: FUJI ELECTRIC CO., LTD., Kanagawa (JP)

(72) Inventor: Koh YOSHIKAWA, Matsumoto-city (JP)

(21) Appl. No.: 18/418,368

(22) Filed: Jan. 22, 2024

(30) Foreign Application Priority Data
Mar. 9, 2023 (JP) 2023-036627

(51) Int. Cl. H01L 29/08; H01L 27/06; H01L 29/40; H01L 29/739; H01L 29/861

(52) U.S. Cl. CPC H01L 29/0804; H01L 27/0664; H01L 29/407; H01L 29/7397; H01L 29/8613

(57) ABSTRACT

A semiconductor device including a semiconductor substrate including a transistor portion and a diode portion, where the transistor portion includes a main region provided to be spaced apart from the diode portion and a boundary region provided to be adjacent to the diode portion, the boundary region include a first boundary portion including an emitter region and a second boundary portion including an anode region and a contact region, and the first boundary portion includes an injection suppression region of the second conductivity type alternately provided with the emitter region in a trench extending direction to suppress an injection of a carrier of the second conductivity type.

### BACKGROUND

### 1. Technical Field

The present invention relates to a semiconductor device.

### 2. Related Art

Patent Literature 1 describes a semiconductor device in which an IGBT region and a diode region are provided on the same semiconductor substrate.

### PRIOR ART LITERATURE

### Patent Literature

Patent Literature 1: Japanese Patent Application Publication No. 2020-72137

### BRIEF DESCRIPTION OF THE DRAWINGS

FIG. 1A illustrates an example of a top view of a semiconductor device 100 according to the Example 1.

FIG. 1B is a diagram showing an example of the cross section taken along the line A-A′ in FIG. 1A.

FIG. 1C is a diagram showing an example of the cross section taken along the line a-a′ in FIG. 1A.

FIG. 1D is a diagram showing an example of the cross section taken along the line b-b′ in FIG. 1A.

FIG. 1E is a diagram showing an example of the cross section taken along the line c-c′ in FIG. 1A.

FIG. 1F is a diagram showing an example of the cross section taken along the line d-d′ in FIG. 1A.

FIG. 2A illustrates an example of a top view of the semiconductor device 100 according to the Example 2.

FIG. 2B is a diagram showing an example of the cross section taken along the line A-A′ in FIG. 2A.

FIG. 2C is a diagram showing an example of the cross section taken along the line b-b′ in FIG. 2A.

FIG. 2D is a diagram showing an example of the cross section taken along the line d-d′ in FIG. 2A.

FIG. 3A illustrates an example of a top view of the semiconductor device 100 according to the Example 3.

FIG. 3B is a diagram showing an example of the cross section taken along the line A-A′ in FIG. 3A.

FIG. 3C illustrates an example of an enlarged top view of the injection suppression region 95.

FIG. 3D is a diagram showing an example of the cross section taken along the line b1-b1′ in FIG. 3C.

FIG. 3E is a diagram showing an example of the cross section taken along the line b2-b2′ in FIG. 3C. FIG. 3F is a diagram showing an example of the cross section taken along the line b3-b3′ in FIG. 3C.

FIG. 4 illustrates an example of a top view of the semiconductor device 100 according to the Example 4.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

In the present specification, one side in a direction parallel to a depth direction of a semiconductor substrate is referred to as an “upper” side, and another side is referred to as a “lower” side. One surface of two principal surfaces of a substrate, a layer, or other member is referred to as a front surface, and the other surface is referred to as a back surface. “Upper”, “lower”, “front”, and “back” directions are not limited to a direction of gravity, or a direction of an attachment to a substrate or the like when a semiconductor device is mounted.

In the present specification, technical matters may be described with orthogonal coordinate axes consisting of an X axis, a Y axis, and a Z axis. In the present specification, a plane parallel to a front surface of the semiconductor substrate is referred to as an XY plane, and a depth direction of the semiconductor substrate is referred to as the Z axis. It should be noted that in the present specification, a case where the semiconductor substrate is viewed in a Z axis direction is referred to as a top view.

Each embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each embodiment respectively have opposite polarities.

In the present specification, in a layer or a region specified with N or P, electrons or holes are meant to be majority carriers, respectively. In addition, each of a symbol “+” and a symbol “−” added to N or P represents a layer or a region of a higher doping concentration and a lower doping concentration than that of a layer or a region without the symbol, and a symbol “++” represents a higher doping concentration than “+” while a symbol “−−” represents a lower doping concentration than “−”.

In the present specification, a doping concentration refers to a concentration of a donor or a dopant that has turned into an acceptor. Accordingly, a unit thereof is /cm³. In the present specification, a difference in concentration (that is, a net doping concentration) between the donor and the acceptor may be set as the doping concentration. In this case, the doping concentration can be measured by an SRP method. In addition, a chemical concentration of the donor and the acceptor may also be set as the doping concentration. In this case, the doping concentration can be measured by a SIMS method. If not particularly limited, any of the above may be used as the doping concentration. If not particularly limited, a peak value of a doping concentration distribution in a doping region may be set as the doping concentration in the doping region.

In addition, as used herein, a dosage refers to the number of ions implanted in a wafer per unit area when ions are implanted. Accordingly, a unit thereof is/cm². It should be noted that a dose amount of a semiconductor region can be set as an integrated concentration obtained by integrating doping concentrations over the depth direction of the semiconductor region. A unit of the integrated concentration is/cm². Accordingly, the dose amount and the integrated concentration may be treated as the same. The integrated concentration may also be an integral value up to a half-value width, and in a case of being overlapped by a spectrum of another semiconductor region, the integrated concentration may be derived without an influence of the other semiconductor region.

Therefore, in the present specification, a level of the doping concentration can be read as a level of the dose amount. That is, when the doping concentration of one region is higher than the doping concentration of another region, it can be understood that the dose amount of the one region is higher than the dose amount of the other region.

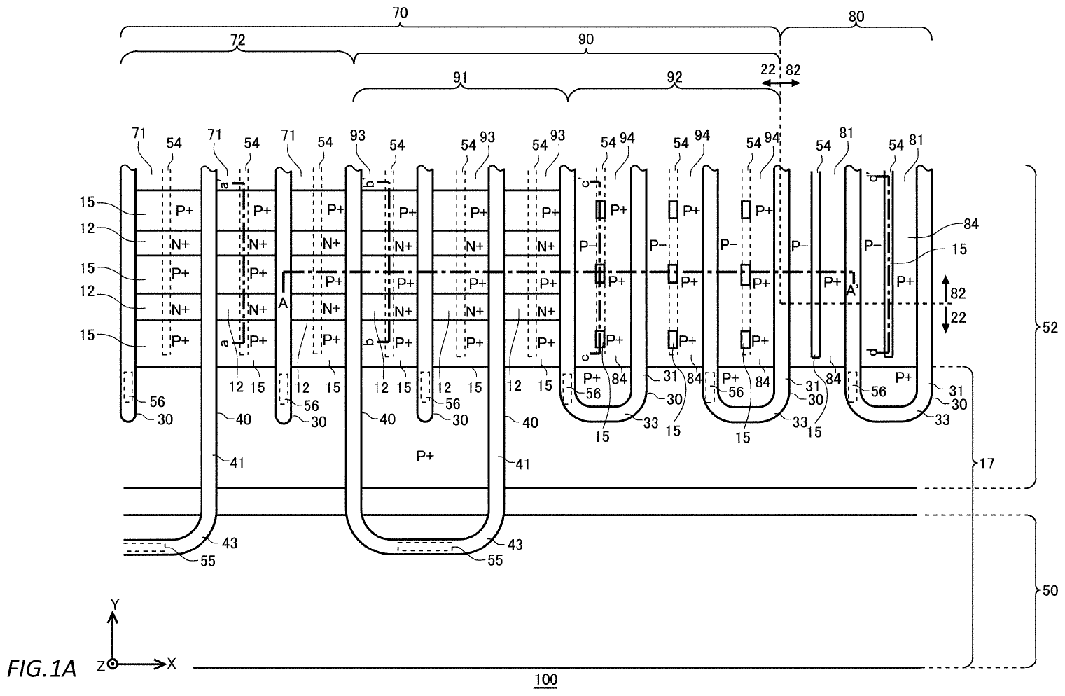

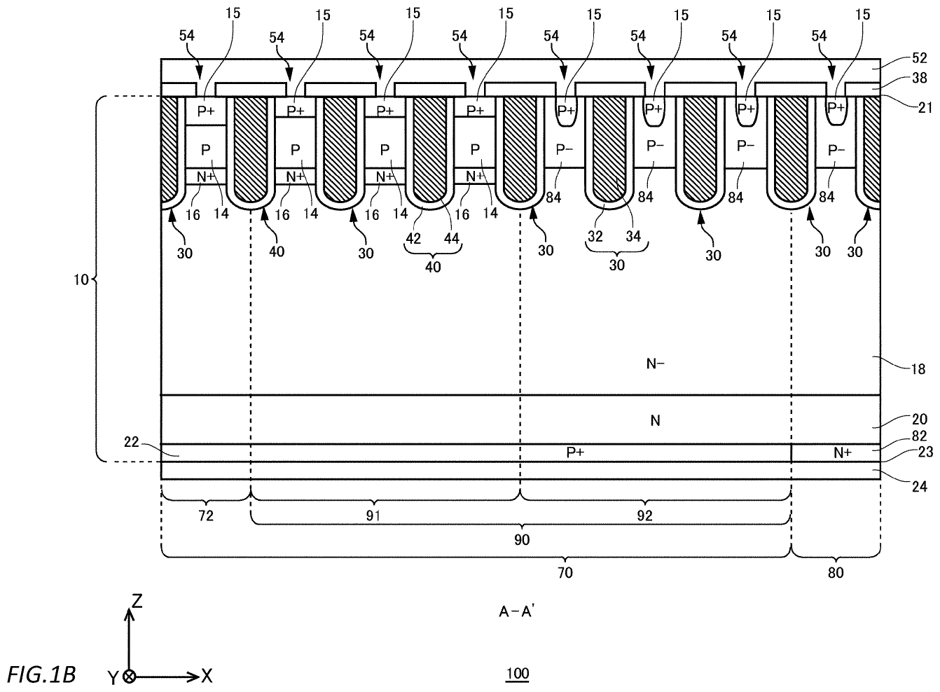

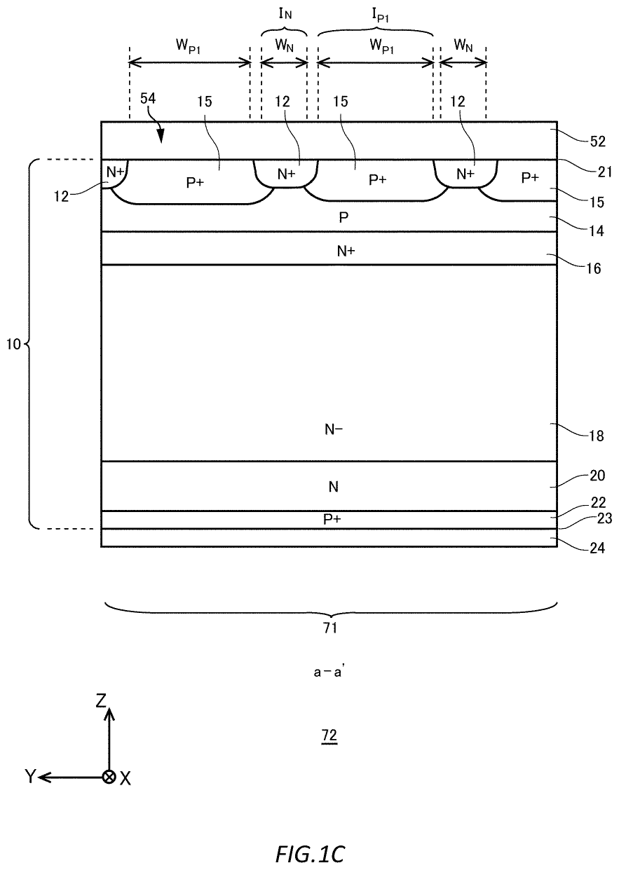

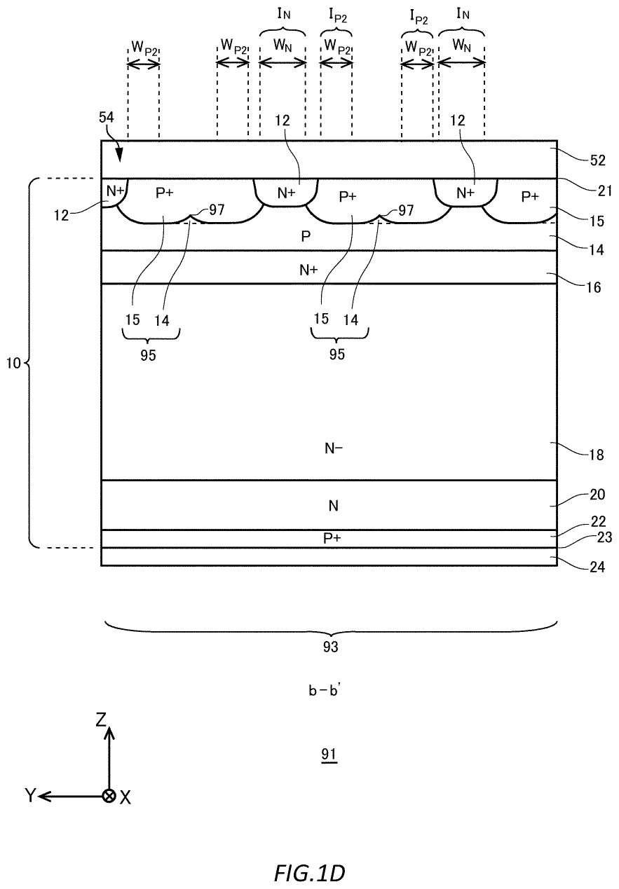

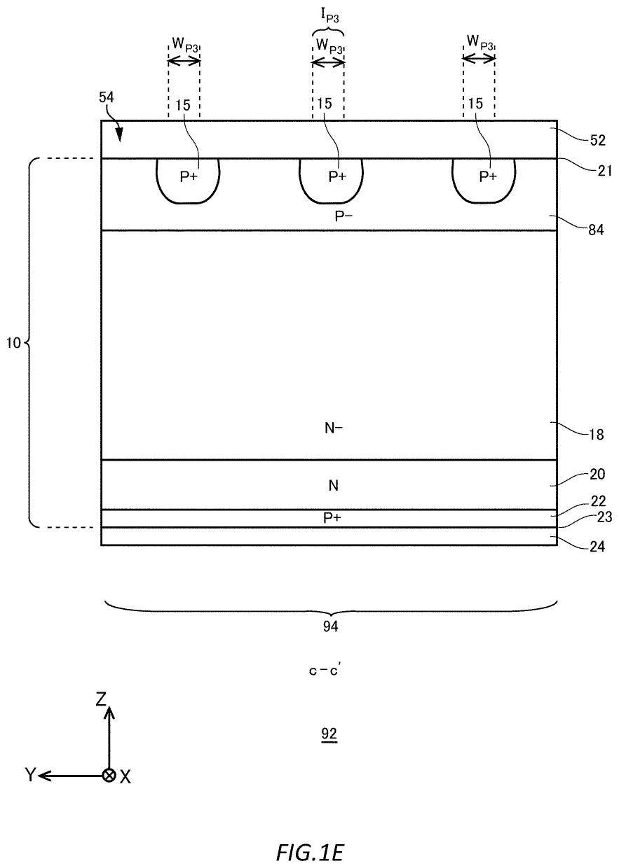

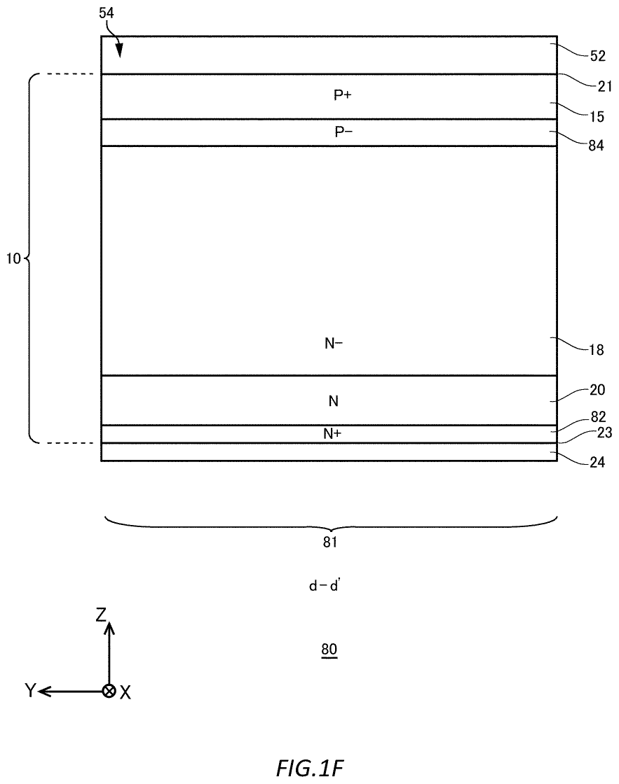

FIG. 1A illustrates an example of a top view of a semiconductor device 100 according to the Example 1. The semiconductor device 100 is provided with the semiconductor substrate having the transistor portion 70 including a transistor element such as an IGBT and the diode portion 80 including a diode element such as a free wheel diode (FWD). For example, the semiconductor device 100 is a reverse conducting IGBT (RC-IGBT).

Note that, in the present specification, when simply referred to as a top view, it means viewing from the front surface side of the semiconductor substrate. In the present example, an array direction of the transistor portion 70 and the diode portion 80 in a top view is referred to as an X axis, a direction perpendicular to the X axis on the front surface of the semiconductor substrate is referred to as a Y axis, and a direction perpendicular to the front surface of the semiconductor substrate is referred to as a Z axis.

Each of the transistor portion 70 and the diode portion 80 may have a longitudinal length in an extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described below may be the same.

The transistor portion 70 is a region where a collector region 22 provided on a back surface side of the semiconductor substrate is projected onto a front surface of a semiconductor substrate. As an example, the collector region 22 of the present example is of the P+ type. The transistor portion 70 includes a transistor such as an IGBT.

In the transistor portion 70, an N type emitter region 12, a P type base region 14, and a gate trench portion 40 including a gate conductive portion and a gate dielectric film are arranged at regular intervals on the front surface side of the semiconductor substrate.

The diode portion 80 is a region where a cathode region 82 provided on the back surface side of the semiconductor substrate is projected onto the front surface of the semiconductor substrate. The cathode region 82 in the present example is of the N+ type as an example. The diode portion 80 includes a diode such as a free wheel diode (FWD: Free Wheel Diode) provided to be adjacent to the transistor portion 70 on the front surface of the semiconductor substrate. The back surface of the semiconductor substrate may be provided with a collector region of the P+ type in a region other than the cathode region.

The semiconductor substrate may be a silicon substrate, a silicon carbide substrate, or a nitride semiconductor substrate and so forth of gallium nitride or the like. The semiconductor substrate of the present example is a silicon substrate.

The semiconductor device 100 of the present example includes a gate trench portion 40, a dummy trench portion 30, an emitter region 12, a base region 14, a contact region 15, a well region 17, an anode region 84, and a contact region 15 provided in the front surface side of the semiconductor substrate. The gate trench portion 40 and the dummy trench portion 30 each are an example of the trench portion.

In addition, the semiconductor device 100 in the present example includes a gate metal layer 50 and an emitter electrode 52 which are provided above the front surface of the semiconductor substrate. An interlayer dielectric film is provided between the emitter electrode 52 and the gate metal layer 50, and the front surface of the semiconductor substrate, but it is omitted in FIG. 1A. In the interlayer dielectric film of the present example, contact holes 54, 55, and 56 are provided to extend through the interlayer dielectric film. In FIG. 1A, each of the contact holes is indicated by a dashed line.

The emitter electrode 52 is provided above the gate trench portion 40, the dummy trench portion 30, the emitter region 12, the contact region 15, the well region 17, and the anode region 84. The emitter electrode 52 electrically connects to the emitter region 12, the contact region 15, and the anode region 84 on the front surface of the semiconductor substrate through the contact hole 54. When the base region 14 is exposed to the front surface of the semiconductor substrate, the emitter electrode 52 also electrically connects to the base region 14 on the front surface of the semiconductor substrate through the contact hole 54.

The emitter electrode 52 and the gate metal layer 50 are formed of a material including metal. At least a part of a region of the emitter electrode 52 may be formed of aluminum, or alloy of which main component is aluminum (for example, aluminum-silicon alloy, aluminum-silicon-copper alloy, or the like). At least part of a region of the gate metal layer 50 may be formed of aluminum, or alloy mainly composed of aluminum (for example, aluminum-silicon alloy, aluminum-silicon-copper alloy, or the like).

The emitter electrode 52 and the gate metal layer 50 may include a barrier metal formed of titanium, titanium compound, or the like under the region formed of aluminum and the like. The emitter electrode 52 and the gate metal layer 50 are provided separately from each other.

The contact hole 55 connects a gate conductive portion within the gate trench portion 40 in the transistor portion 70 and the gate metal layer 50. In the contact hole 55, a plug formed of tungsten or the like may be provided through a barrier metal.

The contact hole 56 connects a dummy conductive portion in the dummy trench portion 30 provided in the transistor portion 70 and the diode portion 80 to the emitter electrode 52. In the contact hole 56, a plug formed of tungsten or the like may be provided through a barrier metal.

The gate trench portion 40 is put into an array at a predetermined interval along a predetermined array direction (the X axis direction in the present example). The gate trench portion 40 of the present example may have: two extending portions 41 that extend along an extending direction (the Y axis direction in the present example) which is parallel to the front surface of the semiconductor substrate and which is perpendicular to the array direction; and a connecting portion 43 that connects the two extending portions 41.

Preferably, at least a part of the connecting portion 43 is formed in a curved shape. By connecting end portions of the two extending portions 41 of the gate trench portion 40, an electric field strength at the end portions of the extending portions 41 can be reduced. At the connecting portion 43 of the gate trench portion 40, the gate metal layer 50 may be connected to the gate conductive portion.

The dummy trench portion 30 is a trench portion in which the dummy conductive portion is provided to be electrically connected to the emitter electrode 52. Similar to the gate trench portions 40, the dummy trench portions 30 are arrayed at predetermined intervals along a predetermined array direction (the X axis direction in the present example). Similar to the gate trench portion 40, the dummy trench portion 30 of the present example may be in a U shape on the front surface of the semiconductor substrate. That is, the dummy trench portion 30 may include two extending portions 31, which extend along the extending direction, and the connecting portion 33, which connects two extending portions 31.

The transistor portion 70 of the present example has a structure in which one gate trench portion 40 and two dummy trench portions 30 are repeatedly arrayed. In other words, the transistor portion 70 of the present example has the gate trench portions 40 and the dummy trench portions 30 at a ratio of 1:1. For example, in the transistor portion 70, the extending portions 31 and the extending portions 41 are alternately arrayed in the array direction.

The ratio of the gate trench portions 40 and the dummy trench portions 30 is not limited to that of the present example. The ratio of the gate trench portions 40 and the dummy trench portions 30 may be 1:2, or may also be 2:3. Alternatively, the transistor portion 70 may not be provided with any dummy trench portions 30 and all trench portions therein may be the gate trench portions 40.

The well region 17 is provided to be closer to the front surface of the semiconductor substrate than the drift region 18 which will be described below. The well region 17 is an example of a well region provided on an edge side of the semiconductor device 100. The well region 17 is of the P+ type as an example. The well region 17 is provided within a predetermined range from an end of an active region on a side where the gate metal layer 50 is provided.

A diffusion depth of the well region 17 may be deeper than depths of the gate trench portion 40 and the dummy trench portion 30. Parts of regions of the gate trench portion 40 and the dummy trench portion 30 on a gate metal layer 50 side are provided in the well region 17. Bottoms of ends of the gate trench portion 40 and the dummy trench portion 30 in the extending direction may be covered with the well region 17.

The contact hole 54 is provided above each region of the emitter region 12 and the contact region 15 in the transistor portion 70. The contact hole 54 is provided above the anode region 84 and the contact region 15 in the diode portion 80. No contact holes 54 are provided above the well regions 17 provided at the both ends in the Y axis direction. In this way, the interlayer dielectric film is provided with one or more contact holes 54. The contact hole 54 of the present example may be provided to extend in the Y axis direction.

A mesa portion 71 and a mesa portion 81 are mesa portions provided so as to be in direct contact with the trench portion in a plane parallel to the front surface of the semiconductor substrate. The mesa portion may be a portion of the semiconductor substrate, which is sandwiched by two adjacent trench portions, and may range from the front surface of the semiconductor substrate to a depth at the lowermost bottom of each trench portion. The extending portions of each trench portion may be set to be one trench portion. That is, the region sandwiched between two extending portions may be set to be a mesa portion.

The mesa portion 71 is provided adjacent to at least one of the dummy trench portion 30 or the gate trench portion 40 in the transistor portion 70. The mesa portion 71 includes the well region 17, the emitter region 12, and the contact region 15 on the front surface of the semiconductor substrate. The mesa portion 81 is provided in direct contact with the dummy trench portion 30 in the diode portion 80. The mesa portion 81 includes the well region 17, the anode region 84, and the contact region 15 on the front surface of the semiconductor substrate.

The base region 14 is a region in the transistor portion 70, which is provided on the front surface side of the semiconductor substrate. The base region 14 in this example is the P type by way of example. The doping concentration of the base region 14 of the present example is equal to or greater than 1E16 cm⁻³and equal to or smaller than 1E18 cm⁻³. Note that, the E means 10 to the power of, for example, 1E16 cm⁻³means 1×10¹⁶ cm⁻³.

The anode region 84 is a region provided on the front surface of the semiconductor substrate in the diode portion 80. The anode region 84 of the present example is of the P− type, by way of example. The doping concentration of the anode region 84 of the present example is equal to or greater than 1E16 cm⁻³and equal to or smaller than 5E17 cm⁻³. The doping concentration of the anode region 84 in the present example is lower than a doping concentration of the base region 14. In the present example, by lowering the doping concentration of the anode region 84, holes can be prevented from being injected during the reverse recovery. Note that the doping concentration of the anode region 84 may be the same as the doping concentration of the base region 14 in another example. In this case, the base region 14 and the anode region 84 can be formed in the same process.

The emitter region 12 is a region which is of the same conductivity type as that of the drift region 18, and which has a doping concentration higher than that of the drift region 18. The emitter region 12 in the present example is of the N− type as an example. The doping concentration of the emitter region 12 of the present example is equal to or greater than 1E19 cm⁻³and equal to or smaller than 1E21 cm⁻³. Examples of a dopant of the emitter region 12 include arsenic (As).

The emitter region 12 is provided to be in contact with the gate trench portion 40 on the front surface of the mesa portion 71. The emitter regions 12 of the present example are provided to extend from one of two trench portions with the mesa portion 71 interposed therebetween to the other in the X axis direction, and are discretely provided in the Y axis direction. The emitter region 12 may or may not be in contact with the dummy trench portion 30. The emitter region 12 of the present example is in contact with the dummy trench portion 30. The emitter region 12 is not provided in the mesa portions 81.

The contact region 15 is a region of the same conductivity type as the base region 14 and the anode region 84, and having a doping concentration higher than those of the base region 14 and the anode region 84. The contact region 15 in the present example is of the P+ type as an example. The doping concentration of the contact region 15 of the present example is equal to or greater than 1E18 cm⁻³and equal to or smaller than 1E21 cm⁻³.

The contact region 15 of the present example is provided on the front surface of the mesa portion 71. The contact regions 15 of the present example are provided to extend from one of two trench portions with the mesa portion 71 interposed therebetween to the other in the X axis direction, and are discretely provided in the Y axis direction. The contact regions 15 of the present example are alternately provided with the emitter regions 12 in the Y axis direction.

The contact region 15 of the present example is also provided on the front surface of the mesa portion 81. The contact region 15 of the present example is provided to extend in the Y axis direction in the mesa portion 81. The contact region 15 may be provided along the lower end of the contact hole 54 in the mesa portion 81. The mesa portion 81 is provided with the contact region 15 so that a lower doping concentration of the anode region 84 can be supplemented and an ohmic junction can be ensured.

The contact region 15 of the present example is provided to be spaced apart from the side wall of the dummy trench portion 30 in the mesa portion 81. On the front surface of the mesa portion 81, the anode region 84 is exposed to a region which is not provided with the contact region 15. That is, the contact region 15 of the present example is surrounded by the anode region 84 in a top view.

In the present example, on the front surface of the mesa portion 71, the emitter regions 12 and the contact regions 15 are alternately provided in the Y axis direction. On the other hand, on the front surface of the mesa portion 81, the contact regions 15 having a higher doping concentration are discretely provided and the anode region 84 having a lower doping concentration is provided. In this manner, the total amount of holes in the mesa portion 81 in reduced so that an injection of holes can be suppressed when a current is conductive in the forward direction.

The transistor portion 70 of the present example includes a main region 72 provided to be spaced apart from the diode portion 80 and a boundary region 90 provided to be adjacent to the diode portion 80. In other words, a region other than the boundary region 90 in the transistor portion 70 is referred to as the main region 72. Although the boundary region 90 is a part of the transistor portion 70, is has a front surface structure different from that of another region in the transistor portion 70 described above (that is, the main region 72). In the present specification, a different configuration from the another region of the transistor portion 70 among configurations of the boundary region 90 will be mainly described, and description of a common configuration will be omitted.

The boundary region 90 of the present example includes a first boundary portion 91 provided to be adjacent to the main region 72 and a second boundary portion 92 provided to be adjacent to the diode portion 80. A width of the boundary region 90 of the present example in the X axis direction is equal to or greater than 50 μm and equal to or smaller than 200 μm. A width of the boundary region 90 of the present example in the X axis direction is equal to or greater than 0.5 times and equal to or smaller than twice the thickness of the semiconductor substrate. A width of the first boundary portion 91 of the present example in the X axis direction is equal to or greater than 50 μm and equal to or smaller than 150 μm. A width of the second boundary portion 92 of the present example in the X axis direction is equal to or greater than 20 μm and equal to or smaller than 100 μm.

The first boundary portion 91 of the present example includes the gate trench portion 40 and the dummy trench portion 30. The first boundary portion 91 includes a mesa portion 93 provided to be adjacent to at least one of the dummy trench portion 30 or the gate trench portion 40. The mesa portion 93 includes the well region 17, the emitter region 12, and the contact region 15 on the front surface of the semiconductor substrate. The mesa portion 93 may further include the base region 14 on the front surface of the semiconductor substrate.

The emitter region 12 is provided to be in contact with the gate trench portion 40 on the front surface of the mesa portion 93. The emitter regions 12 of the present example are provided to extend from one of two trench portions with the mesa portion 93 interposed therebetween to the other in the X axis direction, and are discretely provided in the Y axis direction. On the front surface of the mesa portion 93, both ends of the emitter region 12 in the Y axis direction are in contact with the contact regions 15.

A pitch of the emitter regions 12 of the first boundary portion 91 in the Y axis direction is the same as a pitch of the emitter regions 12 of the main region 72 in the Y axis direction. In present specification, a pitch refers to a distance between a center position of one element in a particular direction, from among a plurality of elements at regular intervals arrayed in the particular direction, and a center position of an adjacent element in the particular direction.

The contact regions 15 are provided, on the front surface of the mesa portion 93, to extend from one of two trench portions with the mesa portion 93 interposed therebetween to the other in the X axis direction, and are discretely provided in the Y axis direction. The contact regions 15 of the present example are alternately provided with the emitter regions 12 in the Y axis direction.

The second boundary portion 92 of the present example includes the dummy trench portion 30, but does not include the gate trench portion 40. The second boundary portion 92 includes a mesa portion 94 provided to be adjacent to the dummy trench portion 30. The mesa portion 94 includes the well region 17, the contact region 15, and the anode region 84 on the front surface of the semiconductor substrate.

On the front surface of the mesa portion 94, the contact regions 15 are discretely provided in the Y axis direction. The contact region 15 may be provided along the lower end of the contact hole 54 in the mesa portion 94. The contact region 15 in the mesa portion 94 is provided to be spaced apart from the side wall of the dummy trench portion 30 in the X axis direction. In the mesa portion 94, a region which is not provided with the contact region 15 is provided with the anode region 84. That is, in a top view, on the front surface of the mesa portion 94, the contact regions 15 are surrounded by the anode region 84 to be arrayed in a dotted pattern.

An area ratio of the contact region 15 on the front surface of the mesa portion 94 is smaller than an area ratio of the contact region 15 on the front surface of the mesa portion 81. That is, the total amount of holes in the second boundary portion 92 of the present example is further reduced than that of the diode portion 80 so that an injection of holes can be suppressed when being conductive in the forward direction.

FIG. 1B is a diagram showing an example of the cross section taken along the line A-A′ in FIG. 1A. The cross section taken along the line A-A′ is an XZ plane passing through the contact region 15.

The semiconductor device 100 in the present example has a semiconductor substrate 10, an interlayer dielectric film 38, the emitter electrode 52, and a collector electrode 24. The emitter electrode 52 is provided above the semiconductor substrate 10 and the interlayer dielectric film 38.

The drift region 18 is a region provided in the semiconductor substrate 10. The drift region 18 in the present example is of the N− type as an example. The drift region 18 may be a region that has remained without other doping regions being formed in the semiconductor substrate 10. That is, the doping concentration of the drift region 18 may be a doping concentration of the semiconductor substrate 10.

The buffer region 20 is a region provided below the drift region 18. The buffer region 20 of the present example may be of the same conductivity type as that of the drift region 18, and is of the N type as an example. The doping concentration of the buffer region 20 is higher than the doping concentration of the drift region 18. The buffer region 20 may function as a field stop layer for preventing a depletion layer, which spreads from the lower surface side of the base region 14, from reaching the collector region 22 and the cathode region 82.

The collector region 22 is a region which is provided below the buffer region 20 in the transistor portion 70 and which is of a conductivity type different from that of the drift region 18. The cathode region 82 is a region which is provided below the buffer region 20 in the diode portion 80 and which is of the same conductivity type as that of the drift region 18. A boundary between the collector region 22 and the cathode region 82 is a boundary between the transistor portion 70 and the diode portion 80.

The collector electrode 24 is provided on a back surface 23 of the semiconductor substrate 10, and is in contact with both the collector region 22 and the cathode region 82. The collector electrode 24 is formed of a conductive material such as metal, or by stacking conductive materials.

The base region 14 is a region other than the second boundary portion 92 in the transistor portion 70, that is, a region of the conductivity type different from that of the drift region 18, provided above the drift region 18 in the main region 72 and the first boundary portion 91. The base region 14 in this example is the P type by way of example. The base region 14 is provided in contact with the gate trench portion 40. The base region 14 may be provided in contact with the dummy trench portion 30.

The anode region 84 is provided above the drift region 18 in the mesa portion 71 of the boundary region 90 and the mesa portion 81 of the diode portion 80, and is of a different conductivity type from that of the drift region 18. The anode region 84 of the present example is of the P− type, by way of example. A doping concentration of the anode region 84 in the present example is lower than a doping concentration of the base region 14. Note that the doping concentration of the anode region 84 may be the same as the doping concentration of the base region 14 in another example. In this case, the base region 14 and the anode region 84 can be formed in the same process. The anode region 84 is provided so as to be in direct contact with the dummy trench portion 30.

The emitter region 12 is provided between the base region 14 and the front surface 21 of the semiconductor substrate 10. The emitter region 12 of the present example is provided in the mesa portion 71 of the main region 72 and the mesa portion 93 of the first boundary portion 91, but is not provided in the mesa portion 94 of the second boundary portion 92 and the mesa portion 81 of the diode portion 80. The emitter region 12 is provided in contact with the gate trench portion 40. The emitter region 12 may or may not be in contact with the dummy trench portion 30.

When the diode portion 80 is brought into conduction, electron current flows from the cathode region 82 to the anode region 84. When the electron current reaches the anode region 84, conductivity modulation occurs and hole current flows from the anode region 84. In addition, electron current diffused from the cathode region 82 facilitates holes to be injected from the contact region 15 of the transistor portion 70, and thereby hole density increases in the semiconductor substrate 10. As a result, increased time required for the hole to disappear when the diode portion 80 is turned off increases reverse recovery peak current and increases reverse recovery loss.

A technique for preventing such hole current is known, in which a lifetime control region including lifetime killers is provided on the front surface side of the semiconductor substrate. By way of example, the lifetime killers are electron lines implanted to the entire semiconductor substrate or helium, an electron line, or proton etc. implanted to a predetermined depth thereof. The lifetime control region is crystal defect formed in the semiconductor substrate by implanting the lifetime killers. The lifetime control region facilitates electrons and holes, which are generated when a diode portion is brought into conduction, to be eliminated in recombination, and thus reduces reverse recovery losses.

In the present example, a lifetime control region including a lifetime killer is not provided in the front surface 21 side of the semiconductor substrate 10. In the present example, in the mesa portion 94 of the second boundary portion 92, the contact regions 15 having a higher doping concentration are discretely provided and the doping concentration of the anode region 84 is made lower than the doping concentration of the base region 14 so that an injection of holes can be suppressed during the reverse recovery even if the lifetime control region is not provided.

The contact hole 54 is provided penetrating the interlayer dielectric film 38 in a Z axis direction, and electrically connects the emitter electrode 52 and the semiconductor substrate 10. The barrier metal formed of titanium, a titanium compound, or the like may be provided in the contact hole 54. The plug formed of tungsten or the like may be further provided through the barrier metal, in the contact hole 54. The contact hole 54 may also be a trench contact structure which is a concave portion provided on the front surface 21 of the semiconductor substrate 10.

The contact region 15 is provided below the contact hole 54. For example, the contact region 15 is formed by an ion implantation of a dopant such as boron (B) from a lower end of the contact hole 54. In the X axis direction, a width of the contact region 15 may be equal to or greater than a width of a lower end of the contact hole 54. The doping concentration of the contact region 15 of the present example is equal to or greater than 1E18 cm⁻³and equal to or smaller than 1E21 cm⁻³.

The accumulation region 16 is a region provided below the base region 14 in the main region 72 and the first boundary portion 91. The accumulation region 16 of the present example is of the same conductivity type as that of the drift region 18, the N+ type, as an example. Two or more stages of the accumulation regions 16 may also be provided. The accumulation region 16 may not be provided below the anode region 84, that is, in the second boundary portion 92 and the diode portion 80.

The accumulation region 16 is provided to be in contact with the gate trench portion 40. The accumulation region 16 may or may not be in contact with the dummy trench portion 30. The doping concentration of the accumulation region 16 is higher than the doping concentration of the drift region 18. By providing the accumulation region 16, the carrier injection enhancement effect (IE effect) can be increased, and an ON voltage of the transistor portion 70 can be reduced.

One or more gate trench portions 40 and one or more dummy trench portions 30 are provided in the front surface 21 of the semiconductor substrate 10. Each trench portion is provided extending in a depth direction (the Z axis direction) from the front surface 21 of the semiconductor substrate 10 to the drift region 18. In a region provided with at least any one of the emitter region 12, the base region 14, the contact region 15, the accumulation region 16, and the anode region 84, each trench portion also extends through these regions to reach the drift region 18. The configuration of the trench portion extending through the doping region is not limited to the one manufactured in the order of forming the doping region and then forming the trench portion. The configuration of the trench portion extending through the doping region includes a configuration of the doping region being formed between the trench portions after forming the trench portion.

The gate trench portion 40 has a gate trench, a gate dielectric film 42, and the gate conductive portion 44 that are provided at the front surface 21 of the semiconductor substrate 10. The gate dielectric film 42 is provided to cover an inner wall of the gate trench. The gate dielectric film 42 may be formed by oxidizing or nitriding a semiconductor on the inner wall of the gate trench. The gate conductive portion 44 is provided in an inner side than the gate dielectric film 42 in the gate trench. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 at the front surface 21 of the semiconductor substrate 10.

The gate conductive portion 44 includes, in the depth direction of the semiconductor substrate 10, a region opposing the base region 14 adjacent thereto on the side of the mesa portion (the mesa portion 71 or the mesa portion 93), having the gate dielectric film 42 interposed therebetween. When a predetermined voltage is applied to the gate conductive portion 44, a channel is formed to a surface layer being at a boundary within the base region 14 and in contact with the gate trench, due to an electron inversion layer.

The dummy trench portion 30 may have the same structure as the gate trench portion 40. The dummy trench portion 30 has a dummy trench, a dummy dielectric film 32, and a dummy conductive portion 34 which are provided on the front surface 21 side of the semiconductor substrate 10. The dummy dielectric film 32 is provided to cover an inner wall of the dummy trench. The dummy conductive portion 34 is provided in the dummy trench, and is provided in an inner side than the dummy dielectric film 32. The dummy dielectric film 32 insulates the dummy conductive portion 34 from the semiconductor substrate 10. The dummy trench portion 30 is covered by the interlayer dielectric film 38 on the front surface 21 of the semiconductor substrate 10.

The interlayer dielectric film 38 is provided to a front surface 21 of the semiconductor substrate 10. The emitter electrode 52 is provided above the interlayer dielectric film 38. The interlayer dielectric film 38 is provided with one or more contact holes 54 to electrically connect the emitter electrode 52 and the semiconductor substrate 10. Similarly, the contact hole 55 and the contact hole 56 may be provided to extend through the interlayer dielectric film 38.

FIG. 1C is a diagram showing an example of the cross section taken along the line a-a′ in FIG. 1A. The cross section taken along the line a-a′ is a YZ plane along the contact hole 54 in the mesa portion 71 of the main region 72. The cross section taken along the line a-a′ passes through the emitter region 12, the contact region 15, and the base region 14.

The base region 14 is provided above the accumulation region 16. For example, the base region 14 is formed, after forming the trench portion on the front surface 21 of the semiconductor substrate 10, by an ion implantation of a dopant such as boron (B) to the mesa portion 71 from an opening of a mask, and by performing an annealing process for heat diffusion. The doping concentration of the base region 14 of the present example is equal to or greater than 1E16 cm⁻³and equal to or smaller than 1E18 cm⁻³.

The emitter regions 12 are discretely provided in the Y axis direction on the front surface of the mesa portion 71. For example, the emitter region 12 is formed, after forming the base region 14 in the semiconductor substrate 10, by an ion implantation of a dopant such as arsenic (As) to the mesa portion 71 from an opening of a mask, and by performing an annealing process for heat diffusion. FIG. 1C illustrates a range of an ion implantation region I_{N}of the emitter region 12, for convenience. The ion implantation region I_{N} corresponds to an opening of a mask. On the front surface of the mesa portion 71, a width of the emitter region 12 in the Y axis direction is greater than a width W_{N} of the ion implantation region I_{N} in the Y axis direction. The doping concentration of the emitter region 12 of the present example is equal to or greater than 1E19 cm⁻³ and equal to or smaller than 1E21 cm⁻³.

The contact regions 15 are discretely provided in the Y axis direction on the front surface of the mesa portion 71. The contact regions 15 of the present example are alternately provided with the emitter regions 12 in the Y axis direction. For example, the contact region 15 is formed, after forming the base region 14 in the semiconductor substrate 10, by an ion implantation of a dopant such as boron (B) to the mesa portion 71 from an opening of a mask, and by performing an annealing process for heat diffusion. In FIG. 1C, a range of the ion implantation region I_{P1} of the contact region 15 is indicated for the sake of convenience. The ion implantation region I_{P1} corresponds to an opening of a mask. On the front surface of the mesa portion 71, a width of the contact region 15 in the Y axis direction is greater than a width W_{P1}of the ion implantation region I_{P1} in the Y axis direction. The doping concentration of the contact region 15 of the present example is equal to or greater than 1E18 cm⁻³and equal to or smaller than 1E21 cm⁻³.

In the mesa portion 71, the ion implantation region I_{N} and the ion implantation region I_{P1} are spaced apart from each other in the Y axis direction. However, the heat diffusion after the ion implantation causes the emitter regions 12 and the contact regions 15 to be in contact with each other and alternately arrayed in the Y axis direction. In the Z axis direction, a lower end of the contact region 15 may be deeper than a lower end of the emitter region 12. The contact region 15 may be formed before the emitter region 12 or may be formed after the emitter region 12. Annealing processes of the emitter region 12, the contact region 15, and the base region 14 may be individually performed after the ion implantation of each region, or may be performed at the same time after the ion implantations of these regions.

FIG. 1D is a diagram showing an example of the cross section taken along the line b-b′ in FIG. 1A. The cross section taken along the line b-b′ is a YZ plane along the contact hole 54 in the mesa portion 93 of the first boundary portion 91. Similar to the cross section taken along the line a-a′ of FIG. 1C, the cross section taken along the line b-b′ passes through the emitter region 12, the contact region 15, and the base region 14. Here, a difference from FIG. 1C will mainly be described while omitting the description of the common matters.

In the mesa portion 93, the lower end of the contact region 15 includes a concave portion 97 recessed in the Z axis direction. In the concave portion 97, the base region 14 has a convex shape along the lower end of the contact region 15. In the mesa portion 93, the base region 14 of the contact region 15 and the concave portion 97 configure an injection suppression region 95 to suppress an injection of holes. In the first boundary portion 91 of the present example, the emitter regions 12 and the injection suppression regions 95 are alternately provided in the Y axis direction.

A pitch in the Y axis direction and a thickness in the Z axis direction of the emitter region 12 in the mesa portion 93 may be the same as a pitch in the Y axis direction and a thickness in the Z axis direction of the emitter region 12 in the mesa portion 71 illustrated in FIG. 1C. In addition, a pitch in the Y axis direction and a thickness in the Z axis direction of the injection suppression region 95 in the mesa portion 93 may be the same as a pitch in the Y axis direction and a thickness in the Z axis direction of the contact region 15 in the mesa portion 71 illustrated in FIG. 1C. That is, the injection suppression region 95 in the mesa portion 93 may be a region provided to correspond to the contact region 15 in the mesa portion 71.

In FIG. 1D, a range of an ion implantation region I_{P2} of the contact region 15 is indicated for the sake of convenience. The ion implantation region I_{P2} corresponds to an opening of a mask. In the present example, a pair of two ion implantation regions I_{P2} is provided for one contact region 15. The two ion implantation regions I_{P2} are spaced apart from each other in the Y axis direction, and a width W_{P2} of each region in the Y axis direction is smaller than the width W_{P1}of the ion implantation region I_{P1} in the mesa portion 71 in the Y axis direction illustrated in FIG. 1C.

In the mesa portion 93, both ends of the ion implantation region I_{N} in the Y axis direction are spaced apart from each of the ion implantation regions I_{P2}. However, the heat diffusion after the ion implantation causes both ends of the emitter region 12 in the Y axis direction to be in contact with the contact region 15. In addition, the heat diffusion causes dopants injected from a pair of two ion implantation regions I_{P2} to come in contact with each other to form one contact region 15.

An amount of dopants for the ion implantation is proportional to a width of an ion implantation region in the Y axis direction. Therefore, a ratio of an amount of dopants for the ion implantation in the contact region 15 of the mesa portion 93 to an amount of dopants for the ion implantation in the contact region 15 of the mesa portion 71 is 2×W_{P2}/W_{P1}.

An averaged doping concentration of the injection suppression region 95 of the present example is higher than the doping concentration of the base region 14 and lower than the doping concentration of the contact region 15. The averaged doping concentration is an amount of dopants for the ion implantation per unit volume, but does not include an amount of impurities originally included in the semiconductor substrate 10. The averaged doping concentration of the injection suppression region 95 of the present example is a value the total amount of dopants for the ion implantation in the contact region 15 and the base region 14 of the concave portion 97 divided by a volume of the injection suppression region 95. On the front surface of the mesa portion 93, an area ratio of the contact region 15 in the injection suppression region 95 may be equal to or greater than 5% and equal to or smaller than 80% of an area ratio of the contact region 15 in the main region 72.

The concave portion 97 at the lower end of the contact region 15 is formed as a result of the heat diffusion causing dopants injected from different ion implantation regions I_{P2} to be in contact with each other. That is, when a distance between two ion implantation regions I_{P2} in the Y axis direction is smaller, the concave portion 97 is smaller and a ratio of the contact region 15 in the injection suppression region 95 is higher. When a distance between two ion implantation regions I_{P2} in the Y axis direction is larger, on the front surface of the mesa portion 93, the concave portion 97 may also be formed at an upper end of the contact region 15. The contact region 15 of the present example does not include the concave portion 97 on the front surface of the mesa portion 93, and is provided to extend between the adjacent emitter regions 12 in the Y axis direction.

FIG. 1E is a diagram showing an example of the cross section taken along the line c-c′ in FIG. 1A. The cross section taken along the line c-c′ is a YZ plane along the contact hole 54 in the mesa portion 94 of the second boundary portion 92. The cross section taken along the line c-c′ passes through the contact region 15 and the anode region 84. Here, a difference from FIG. 1D will mainly be described while omitting the description of the common matters.

The anode region 84 is provided above the drift region 18. For example, the anode region 84 is formed, after forming the trench portion on the front surface 21 of the semiconductor substrate 10, by an ion implantation of a dopant such as boron (B) to the mesa portion 94 from an opening of a mask, and by performing an annealing process for heat diffusion. The doping concentration of the anode region 84 of the present example is equal to or greater than 1E16 cm⁻³and equal to or smaller than 5E17 cm⁻³. A doping concentration of the anode region 84 in the present example is lower than a doping concentration of the base region 14.

The contact regions 15 are discretely provided in the Y axis direction on the front surface of the mesa portion 94. For example, the contact region 15 is formed, after forming the anode region 84 in the semiconductor substrate 10, by an ion implantation of a dopant such as boron (B) to the mesa portion 94 from an opening of a mask, and by performing an annealing process for heat diffusion. In the mesa portion 94, the contact region 15 may be provided along a lower end of the contact hole 54. In this case, the contact region 15 may be formed, after forming the contact hole 54 in the interlayer dielectric film 38, using the same mask for the ion implantation of dopants from the contact hole 54.

In the mesa portion 94, a region which is not provided with the contact region 15 is provided with the anode region 84. That is, in the mesa portion 94, the contact region 15 is provided to be surrounded by the anode region 84. The emitter region 12 is not provided in the mesa portion 94.

In FIG. 1E, a range of an ion implantation region I_{P3} of the contact region 15 is indicated for the sake of convenience. The ion implantation region I_{P3} corresponds to an opening of a mask. On the front surface of the mesa portion 94, a width of the contact region 15 in the Y axis direction is greater than a width W_{P3}of the ion implantation region I_{P3} in the Y axis direction. A width W_{P3}of the ion implantation region I_{P3} in the Y axis direction may be the same as or may be smaller than the width W_{P2}of the ion implantation region I_{P2} in the Y axis direction illustrated in FIG. 1D.

FIG. 1F is a diagram showing an example of the cross section taken along the line d-d′ in FIG. 1A. The cross section taken along the line d-d′ is a YZ plane along the contact hole 54 in the mesa portion 81 of the diode portion 80. The cross section taken along the line d-d′ passes through the contact region 15 and the anode region 84. Here, a difference from FIG. 1E will mainly be described while omitting the description of the common matters.

In the mesa portion 81, the contact region 15 is provided to extend in the Y axis direction. That is, an area ratio of the contact region 15 on the front surface of the mesa portion 81 is greater than an area ratio of the contact region 15 on the front surface of the mesa portion 94.

In an RC-IGBT of which the transistor portion and the diode portion are provided in the same substrate, holes to be travelled from the contact region of the boundary region of the transistor portion at the diode portion side to the cathode region of the diode portion when a voltage is applied in the forward direction are injected into the semiconductor substrate, thereby increasing a loss during the reverse recovery. However, if an area ratio of the contact region in the boundary region is made smaller, an area of the emitter region is also decreased, which leads to a decline in the transistor characteristics.

According to the semiconductor device 100 of the present example, the boundary region 90 is divided into the first boundary portion 91 of the transistor portion 70 side and the second boundary portion 92 of the diode portion 80 side, where the first boundary portion 91 includes the emitter regions 12 and the injection suppression regions 95 to suppress an injection of holes alternately provided in the Y axis direction. In this manner, the first boundary portion 91 suppresses a decline in the transistor characteristics while suppressing an injection of holes during the reverse recovery.

In addition, in the second boundary portion 92, an area ratio of the contact region 15 is made smaller to reduce the total amount of holes to suppress an injection of holes during the reverse recovery. In this manner, the semiconductor device 100 of the present example can reduce the reverse recovery loss while maintaining the transistor characteristics.

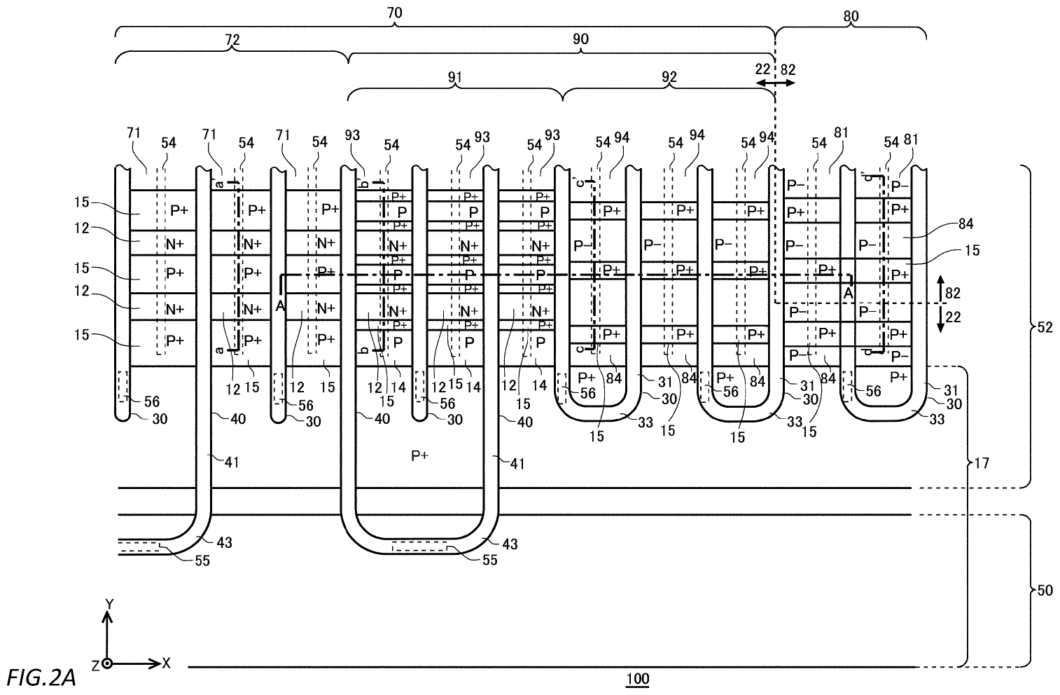

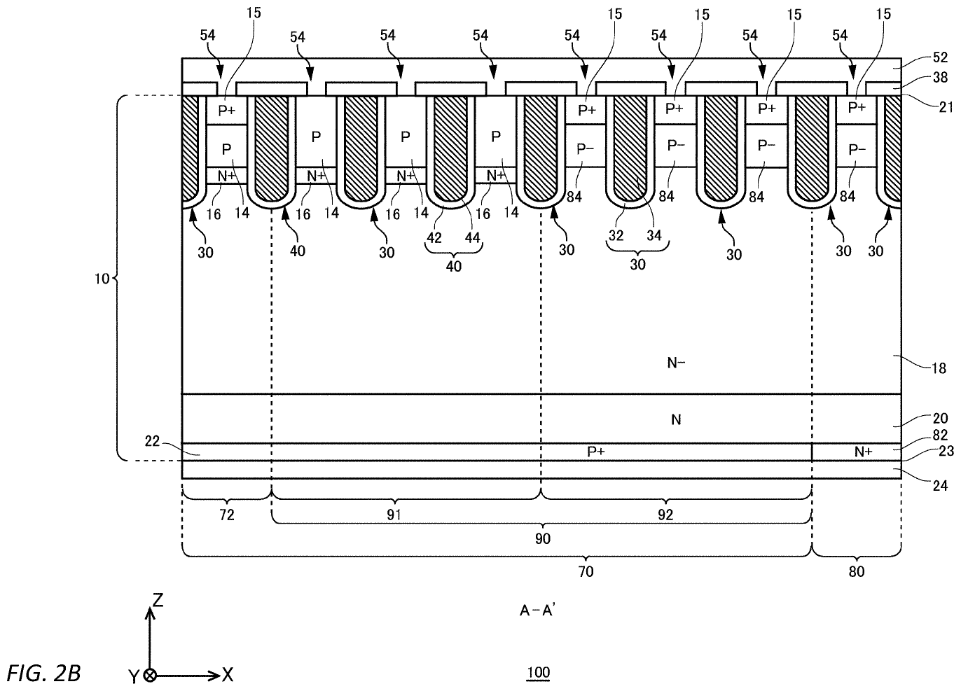

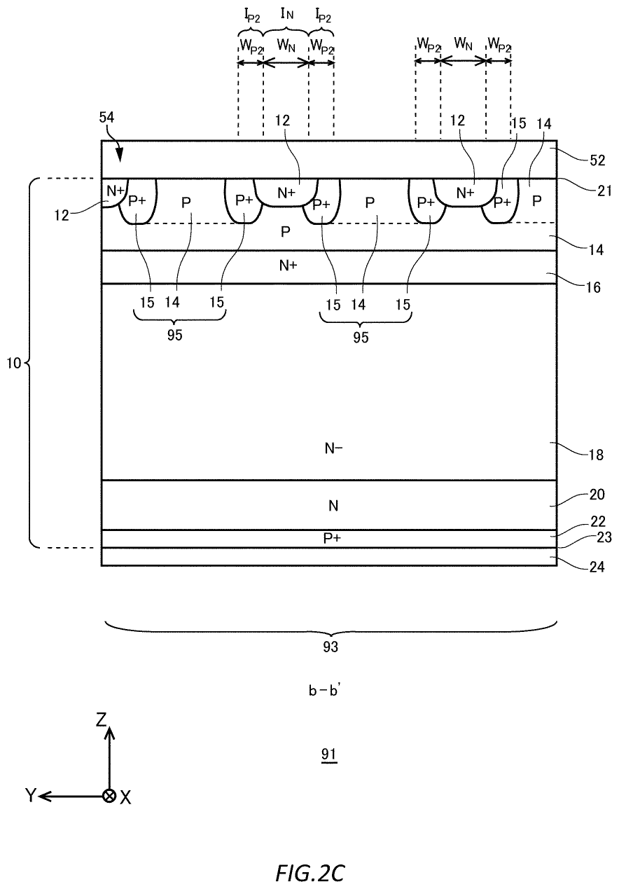

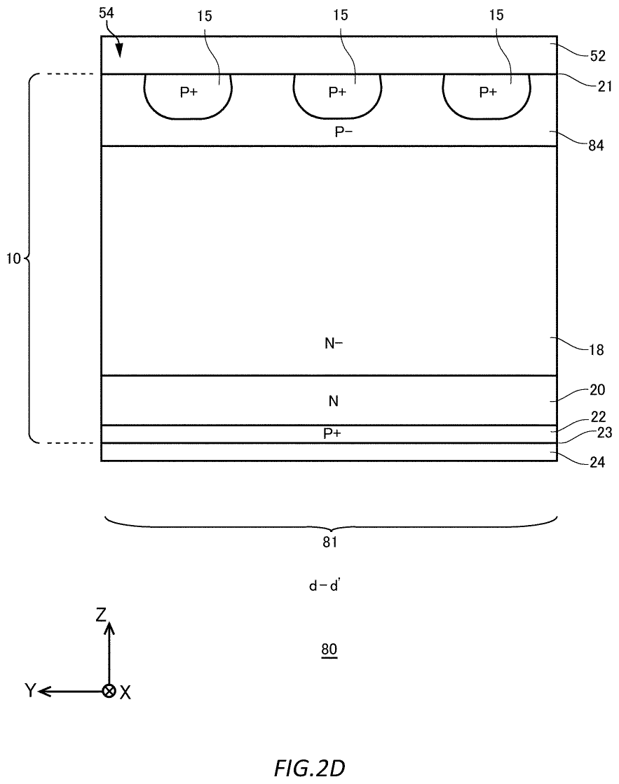

FIG. 2A illustrates an example of a top view of the semiconductor device 100 according to the Example 2. FIG. 2B is a diagram showing an example of the cross section taken along the line A-A′ in FIG. 2A. The Example 2 is different from the Example 1 in the injection suppression region 95 of the first boundary portion 91 where the base region 14 is exposed to the front surface 21 of the semiconductor substrate 10. Here, elements common with the semiconductor device 100 according to the Example 1 are provided with the same reference signs and the descriptions will be omitted.

On the front surface of the mesa portion 93, both ends of the base region 14 of the injection suppression region 95 in the Y axis direction are in contact with the contact region 15. In addition, on the front surface of the mesa portion 93, both ends of the emitter region 12 in the Y axis direction are in contact with the contact regions 15 of the injection suppression region 95. That is, in a top view of the semiconductor substrate 10, the base region 14 is provided at the center position of the injection suppression region 95 in the Y axis direction, and the contact region 15 is provided between the base region 14 and the emitter region 12.

In addition, on the front surface of the mesa portion 94 and the mesa portion 81, the contact regions 15 are discretely provided in the Y axis direction, and provided to extend from one of two dummy trench portions 30 with a mesa portion interposed therebetween, to the other in the X axis direction. A width of the contact region 15 of the mesa portion 94 in the Y axis direction is smaller than a width of the contact region 15 of the mesa portion 81 in the Y axis direction. Note that the cross section taken along the line c-c′ which passes the contact hole 54 of the mesa portion 94 is the same as the cross section taken along the line c-c′ illustrated in FIG. 1E, and therefore the illustration will be omitted.

FIG. 2C is a diagram showing an example of the cross section taken along the line b-b′ in FIG. 2A. In the injection suppression region 95 of the present example, the base region 14 is exposed to the front surface of the mesa portion 93 so that the contact region 15 is divided into two regions in the Y axis direction. The injection suppression region 95 of the present example does not include the concave portion 97. The injection suppression region 95 of the present example is configured with the contact region 15 and a region of the base region 14 above the dashed line illustrated in FIG. 2C.

Both ends of the ion implantation region I_{N} in the Y axis direction of the emitter region 12 of the present example are in contact with the ion implantation region I_{P2}. The width W_{P2}of the ion implantation region I_{P2} in the Y axis direction may be the same as or may be smaller than the width W_{P2} illustrated in FIG. 1D. In the Y axis direction, a distance between the respective ion implantation regions I_{P2} may be greater than a distance between the ion implantation regions I_{P2} illustrated in FIG. 1D.

In operation of the transistor portion 70, a hole current from the collector region 22 travels upward along a side wall of the trench portion and is extracted from the contact hole 54 to the emitter electrode 52. Therefore, first, a current crowding occurs at the side wall of the trench portion. Then, the hole current bypasses the emitter region 12 and flows from the contact region 15 to the contact hole 54 so that a current crowding also occurs at the boundary between the emitter region 12 and the contact region 15.

In the present example, the contact region 15 is provided to be in contact with both ends of the emitter region 12 in the Y axis direction to prevent the latch up due to the current crowding. In addition, the contact regions 15 are provided to be spaced apart from each other and the base region 14 is provided between them to reduce a total amount of holes. This can suppress an injection of holes during the reverse recovery and reduce the reverse recovery loss.

FIG. 2D is a diagram showing an example of the cross section taken along the line d-d′ in FIG. 2A. In the mesa portion 81, the contact regions 15 are discretely provided in the Y axis direction. In addition, the contact regions 15 of the mesa portion 94 which are not illustrated are also discretely provided in the Y axis direction. A width of the contact region 15 of the mesa portion 94 in the Y axis direction is smaller than a width of the contact region 15 of the mesa portion 81 in the Y axis direction.

As described above with respect to FIG. 2C, a total amount of holes in the injection suppression region 95 of the present example is smaller than that of the injection suppression region 95 of the Example 1. Therefore, in the mesa portion 94 and the mesa portion 81 of the present example, a ratio of the contact region 15 can be increased to facilitate an extraction of holes. Alternatively, the contact region 15 of the mesa portion 94 and the mesa portion 81 may have a configuration similar to that of the Example 1.

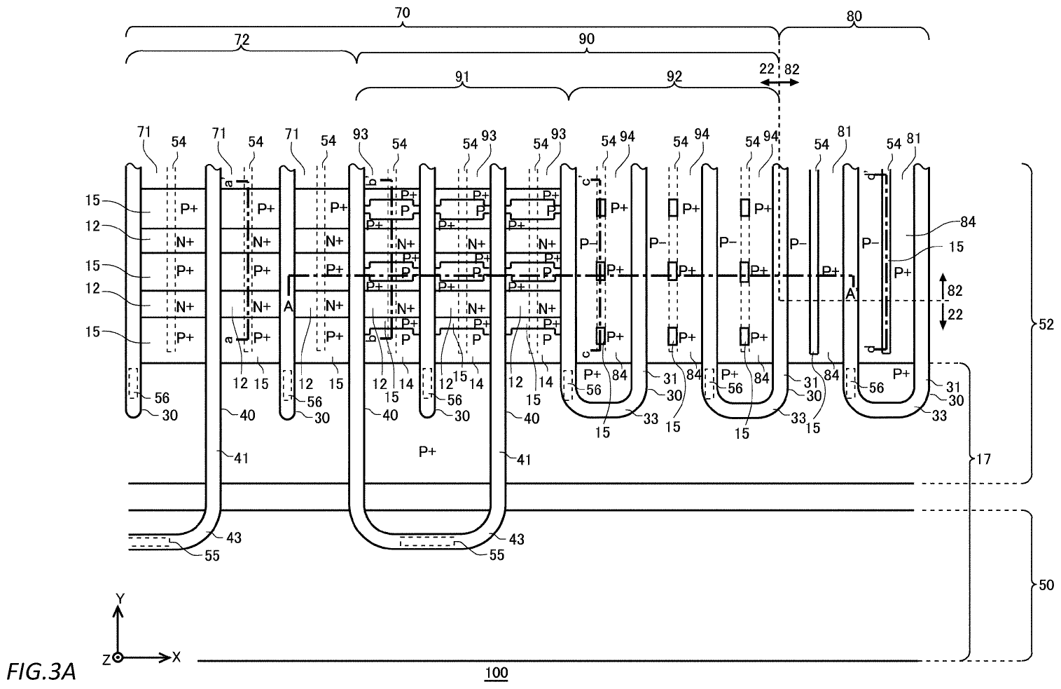

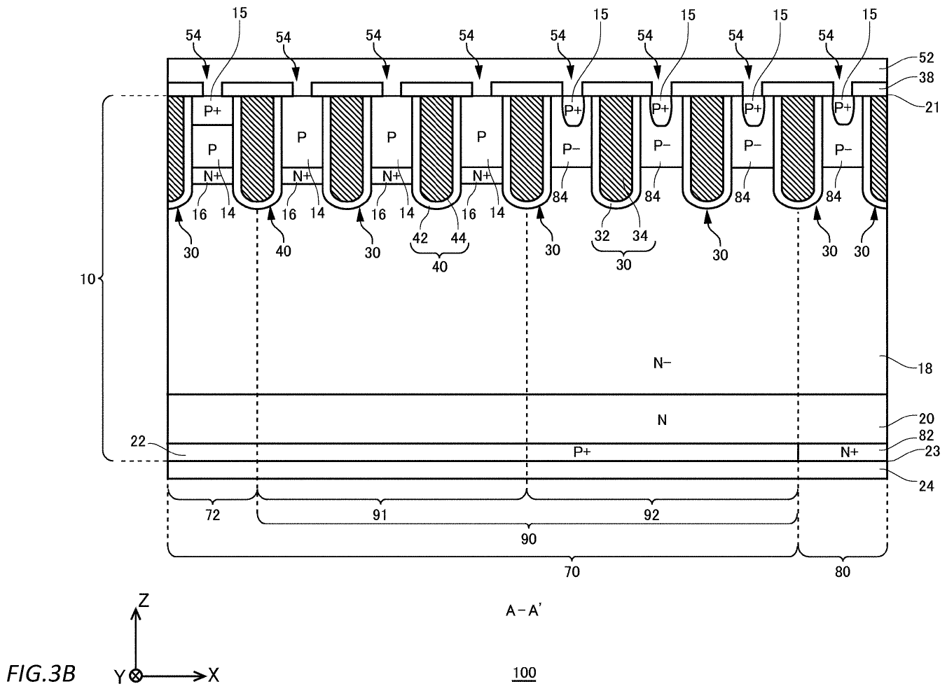

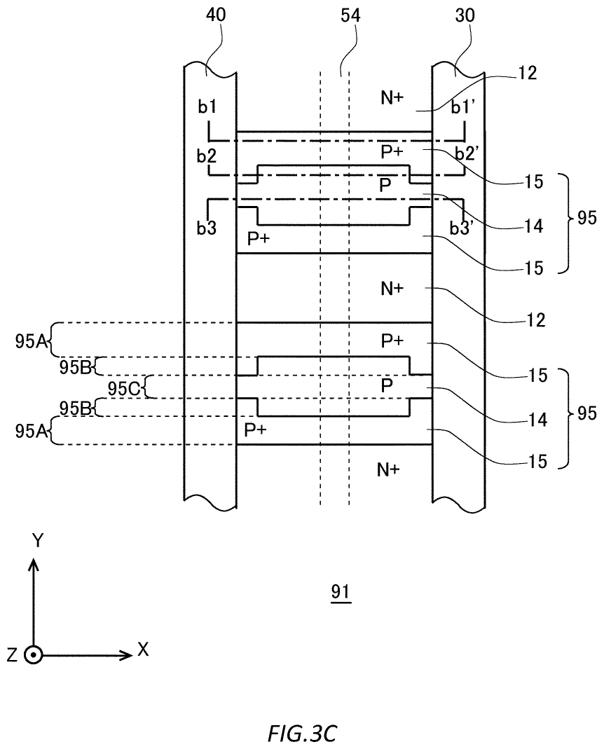

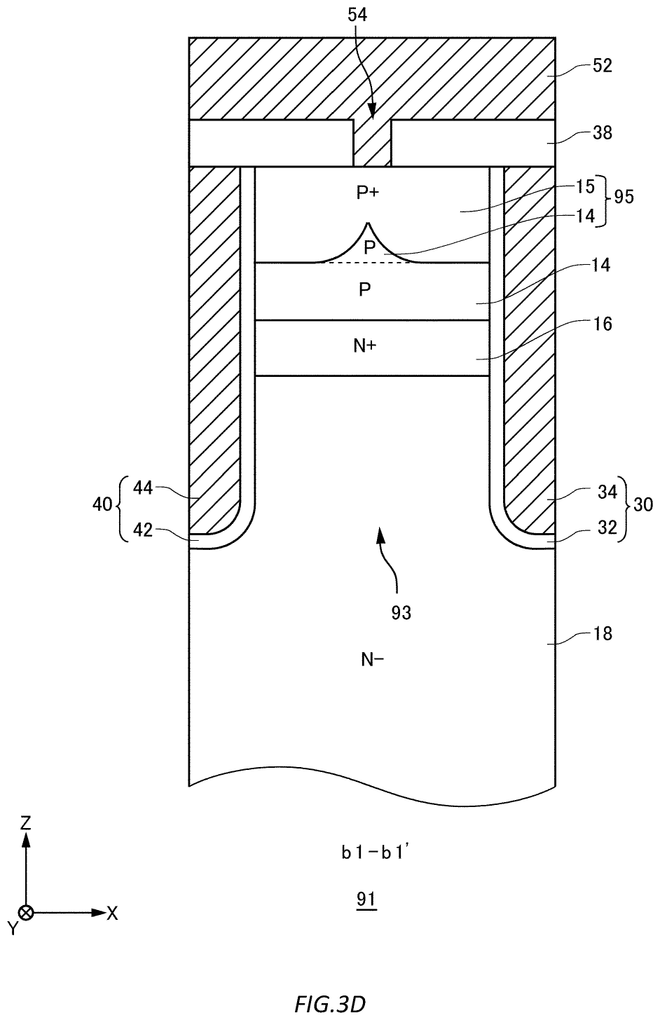

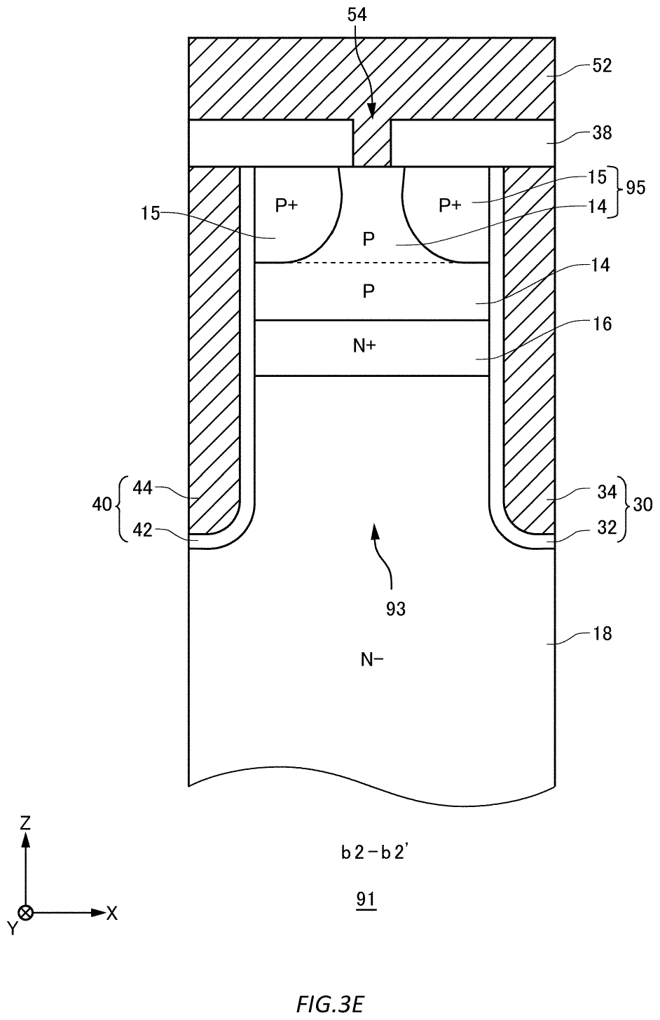

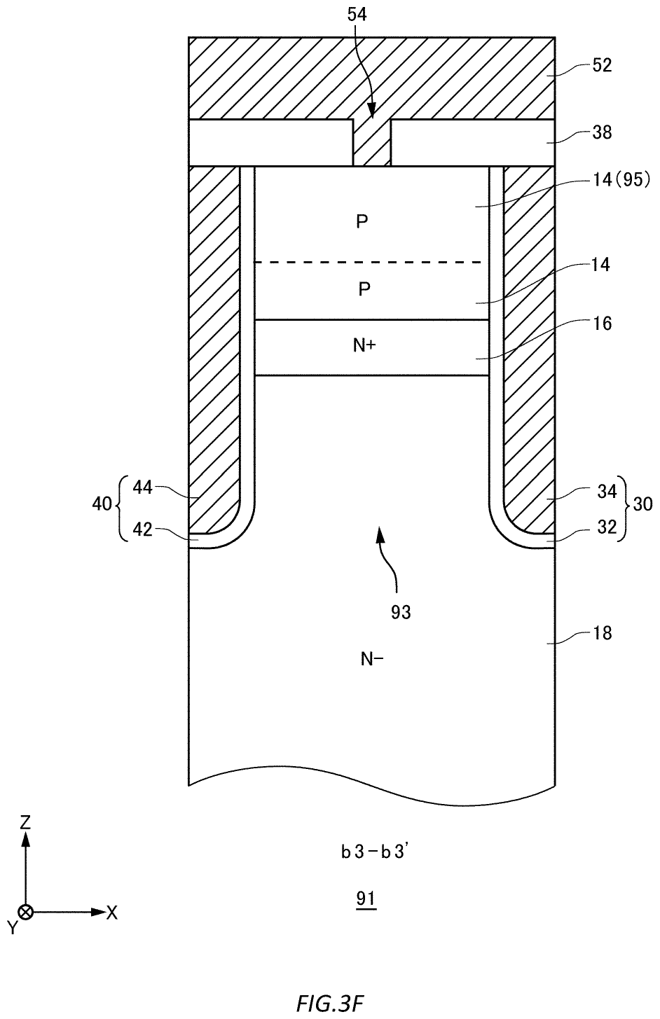

FIG. 3A illustrates an example of a top view of the semiconductor device 100 according to the Example 3. FIG. 3B is a diagram showing an example of the cross section taken along the line A-A′ in FIG. 3A. FIG. 3C illustrates an example of an enlarged top view of the injection suppression region 95. The Example 3 is different from the Example 2 in the arrangement of the contact region 15 and the base region 14 of the mesa portion 93 in the first boundary portion 91, as illustrated in FIG. 3A and FIG. 3B. The injection suppression region 95 is configured with the contact region 15 and the base region 14 in the mesa portion 93. Here, elements common with the semiconductor device 100 according to the Example 2 are provided with the same reference signs and the descriptions will be omitted.

As illustrated in FIG. 3C, the injection suppression region 95 includes a first region 95A including the contact region 15 on the front surface of the mesa portion 93, provided to extend from one trench portion to the other opposing trench portion. The first region 95A is provided to be in contact with the emitter region 12 in the Y axis direction.

Further, the injection suppression region 95 includes a second region 95B including, on the front surface of the mesa portion 93, the contact region 15 provided to be in contact with the side walls of two opposing trench portions, and the base region 14 provided to be spaced apart from these trench portions. The second region 95B is provided to be in contact with the first region 95A in the Y axis direction.

Further, the injection suppression region 95 includes a third region 95C including the base region 14 on the front surface of the mesa portion 93, provided to extend from one trench portion to the other opposing trench portion. The third region 95C is provided to be in contact with the second region 95B in the Y axis direction.

FIG. 3D is a diagram showing an example of the cross section taken along the line b1-b1′ in FIG. 3C. FIG. 3E is a diagram showing an example of the cross section taken along the line b2-b2′ in FIG. 3C. FIG. 3F is a diagram showing an example of the cross section taken along the line b3-b3′ in FIG. 3C. Each of FIG. 3D to FIG. 3F is an XZ plane passing through the first region 95A, the second region 95B, and the third region 95C of the injection suppression region 95.

As can be seen from FIG. 3D and FIG. 3E, a thickness of the contact region 15 of the first region 95A is greater than a thickness of the contact region 15 of the second region 95B. That is, a ratio of the base region 14 in the second region 95B is higher than a ratio of the base region 14 in the first region 95A. The contact region 15 of the first region 95A and the second region 95B of the present example may be formed by the heat diffusion of dopants implanted in one ion implantation.

As described above with respect to FIG. 2C, in operation of the transistor portion 70, a current crowding occurs at the side wall of the trench portion and the boundary between the emitter region 12 and the contact region 15. In the injection suppression region 95 of the present example, the third region 95C of a lower risk of a current crowding is only provided with the base region 14 while a ratio of the contact region 15 in the first region 95A where the current crowding occurs is increased, so that the reverse recovery loss can be reduced while preventing the latch up.

Alternatively, the injection suppression region 95 may only include the first region 95A and the second region 95B and may not include the third region 95C. In this case, the contact region 15 of the injection suppression region 95 is provided to extend along the side wall of the trench portion so that the latch up can be prevented more effectively.

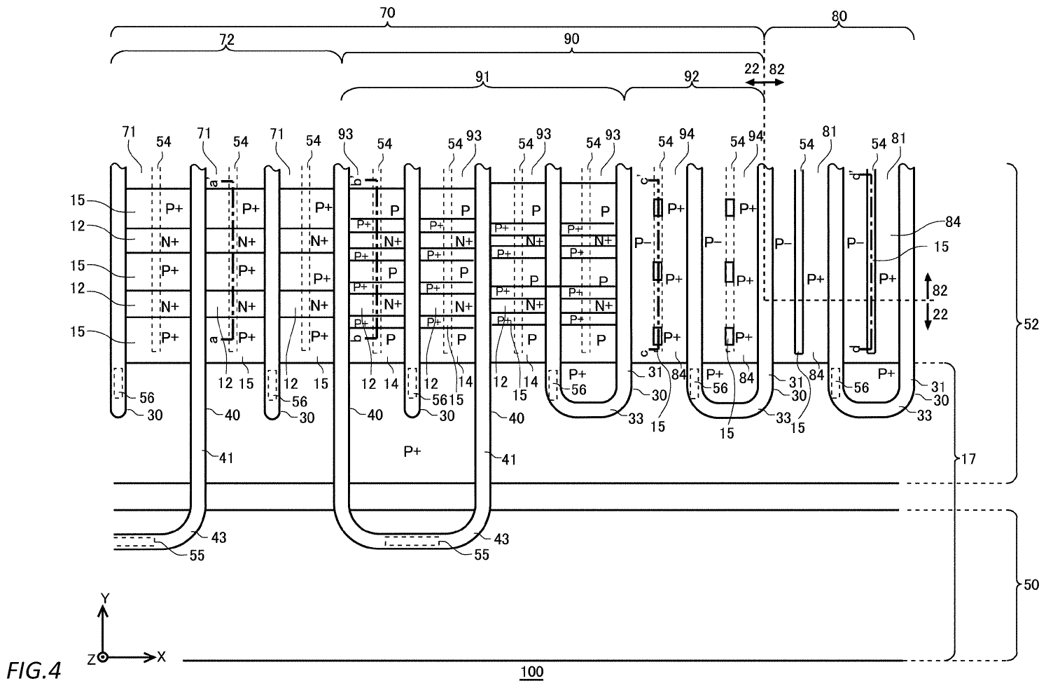

FIG. 4 illustrates an example of a top view of the semiconductor device 100 according to the Example 4. The Example 4 is different from the Example 2 in a width of the emitter region 12 in the first boundary portion 91 in the Y axis direction being varied. Here, elements common with the semiconductor device 100 according to the Example 2 are provided with the same reference signs and the descriptions will be omitted.

The width of the emitter region 12 in the first boundary portion 91 in the Y axis direction is smaller than the width of the emitter region 12 in the main region 72 in the Y axis direction. In addition, the width of the emitter region 12 in the first boundary portion 91 in the Y axis direction is smaller at a location closer to the diode portion 80 in the X axis direction. Note that a pitch of the emitter regions 12 of the first boundary portion 91 in the Y axis direction is the same as a pitch of the emitter regions 12 of the main region 72 in the Y axis direction. In addition, the width of the contact region 15 in the injection suppression region 95 in the Y axis direction is constant.

In the first boundary portion 91, only a width of the emitter region 12 is smaller while a pitch thereof is constant in the Y axis direction so that a ratio of the injection suppression region 95 interposed between the emitter regions 12, that is, a ratio of the base region 14 is raised. In the first boundary portion 91 of the present example, a ratio of the emitter region 12 is increased in a region closer to the main region 72 to suppress a decline in the transistor characteristics. In addition, in a region closer to the diode portion 80, an area ratio of the contact region 15 is made smaller to reduce the total amount of holes to suppress an injection of holes during the reverse recovery. In this manner, the semiconductor device 100 of the present example can reduce the reverse recovery loss while maintaining the transistor characteristics.

While the present invention has been described by way of the embodiments, the technical scope of the present invention is not limited to the above described embodiments. It is apparent to persons skilled in the art that various alterations or improvements can be made to the above described embodiments. It is also apparent from description of the claims that the embodiments to which such alterations or improvements are made can be included in the technical scope of the present invention.

It should be noted that the operations, procedures, steps, stages, and the like of each processing performed by an apparatus, system, program, and method shown in the claims, specification, or drawings can be realized in any order as long as the order is not indicated by “prior to,” “before,” or the like and as long as the output from a previous processing is not used in a later processing. Even if the operation flow is described using phrases such as “first” or “next” for the sake of convenience in the claims, specification, or drawings, it does not necessarily mean that the process must be performed in this order.

### EXPLANATION OF REFERENCES

10: semiconductor substrate, 12: emitter region, 14: base region, 15: contact region, 16: accumulation region, 17: well region, 18: drift region, 20: buffer region, 21: front surface, 22: collector region, 23: back surface, 24: collector electrode, 30: dummy trench portion, 31: extending portion, 33: connecting portion, 32: dummy dielectric film, 34: dummy conductive portion, 38: interlayer dielectric film, 40: gate trench portion, 41: extending portion, 43: connecting portion, 42: gate dielectric film, 44: gate conductive portion, 50: gate metal layer, 52: emitter electrode, 54: contact hole, 55: contact hole, 56: contact hole, 70: transistor portion, 71: mesa portion, 80: diode portion, 81: mesa portion, 82: cathode region, 84: anode region, 90: boundary region, 91: first boundary portion, 92: second boundary portion, 93: mesa portion, 94: mesa portion, 95: injection suppression region, 97: concave portion, 100: semiconductor device

What is claimed is:

1. A semiconductor device comprising a semiconductor substrate including a transistor portion and a diode portion, wherein the semiconductor substrate includes:
a plurality of trench portions provided on a front surface of the semiconductor substrate and including a gate trench portion;
a drift region of a first conductivity type provided in the semiconductor substrate;
a base region of a second conductivity type provided above the drift region in the transistor portion;
an emitter region of the first conductivity type provided on the front surface of the semiconductor substrate and having a doping concentration higher than that of the drift region;
a contact region of the second conductivity type provided on the front surface of the semiconductor substrate and having a doping concentration higher than that of the base region; and
an anode region of the second conductivity type provided above the drift region in the diode portion and having a doping concentration lower than that of the contact region, wherein
the transistor portion includes a main region provided to be spaced apart from the diode portion and a boundary region provided to be adjacent to the diode portion,
the boundary region includes a first boundary portion including the emitter region and a second boundary portion including the anode region and the contact region, and
the first boundary portion includes an injection suppression region of the second conductivity type alternately provided with the emitter region in a trench extending direction to suppress an injection of a carrier of the second conductivity type.

2. The semiconductor device according to claim 1, wherein
an averaged doping concentration of the injection suppression region is higher than the doping concentration of the base region and lower than the doping concentration of the contact region.

3. The semiconductor device according to claim 1, wherein
the injection suppression region includes the base region and the contact region.

4. The semiconductor device according to claim 3, wherein
on the front surface of the semiconductor substrate, an area ratio of the contact region in the injection suppression region is equal to or greater than 5% and equal to or smaller than 80% of an area ratio of the contact region in the main region.

5. The semiconductor device according to claim 1, wherein
a width of the boundary region in a trench array direction is equal to or greater than 50 μm and equal to or smaller than 200 μm.

6. The semiconductor device according to claim 1, wherein
a width of the boundary region in a trench array direction is equal to or greater than 0.5 times and equal to or smaller than twice a thickness of the semiconductor substrate.

7. The semiconductor device according to claim 1, wherein
a width of the first boundary portion in a trench array direction is equal to or greater than 50 μm and equal to or smaller than 150 μm.

8. The semiconductor device according to claim 1, wherein
the first boundary portion includes the gate trench portion.

9. The semiconductor device according to claim 1, wherein
the contact region in the second boundary portion includes a plurality of contact regions discretely provided in the trench extending direction.

10. The semiconductor device according to claim 9, wherein
on the front surface of the semiconductor substrate, an area ratio of the contact region in the second boundary portion is smaller than an area ratio of the contact region in the diode portion.

11. The semiconductor device according to claim 1, wherein
a width of the second boundary portion in a trench array direction is equal to or greater than 20 μm and equal to or smaller than 100 μm.

12. The semiconductor device according to claim 1, wherein
the plurality of trench portions includes a dummy trench portion, and
the second boundary portion includes the dummy trench portion and does not include the gate trench portion.

13. The semiconductor device according to claim 1, wherein
the emitter region includes a plurality of emitter regions discretely provided in the trench extending direction, and
the injection suppression region includes a plurality of injection suppression regions provided between the plurality of emitter regions in the trench extending direction.

14. The semiconductor device according to claim 4, wherein
a lower end of the contact region in the injection suppression region includes a concave portion which is recessed in a depth direction of the semiconductor substrate.

15. The semiconductor device according to claim 2, wherein
on the front surface of the semiconductor substrate, the base region in the injection suppression region has both ends in contact with the contact regions in the trench extending direction.

16. The semiconductor device according to claim 5, wherein
on the front surface of the semiconductor substrate, both ends of the emitter region in the first boundary portion in the trench extending direction are in contact with the contact regions in the injection suppression region.

17. The semiconductor device according to claim 15, wherein
the contact region in the second boundary portion is provided to extend from one trench portion to the other opposing trench portion in a trench array direction.

18. The semiconductor device according to claim 1, wherein
on the front surface of the semiconductor substrate, the injection suppression region includes a first region including the contact region provided to extend from one trench portion to the other opposing trench portion, and
the first region is provided to be in contact with the emitter region.

19. The semiconductor device according to claim 18, wherein
on the front surface of the semiconductor substrate, the injection suppression region includes a second region including the contact region provided to be in contact with side walls of two trench portions opposing to each other and the base region provided to be spaced apart from the two opposing trench portions, and
the second region is provided to be in contact with the first region.

20. The semiconductor device according to claim 17, wherein
on the front surface of the semiconductor substrate, the injection suppression region includes a third region including the base region provided to extend from one trench portion to the other opposing trench portion.

21. The semiconductor device according to claim 1, wherein
a width of the emitter region in the first boundary portion in the trench extending direction is smaller than a width of the emitter region in the main region in the trench extending direction.

22. The semiconductor device according to claim 21, wherein
a width of the emitter region in the first boundary portion in the trench extending direction is smaller at a location closer to the diode portion in a trench array direction.

23. The semiconductor device according to claim 21, wherein
a pitch of the emitter region in the first boundary portion in the trench extending direction is the same as a pitch of the emitter region in the main region in the trench extending direction.

24. The semiconductor device according to claim 1, wherein
the diode portion includes the contact region provided to extend in the trench extending direction.

25. The semiconductor device according to claim 1, wherein
the doping concentration of the contact region is equal to or greater than 1E18 cm⁻³ and equal to or smaller than 1E21 cm⁻³.

26. The semiconductor device according to claim 1, wherein
the doping concentration of the base region is equal to or greater than 1E16 cm⁻³ and equal to or smaller than 1E18 cm⁻³.

27. The semiconductor device according to claim 1, wherein
the doping concentration of the anode region is the same as the doping concentration of the base region.

28. The semiconductor device according to claim 1, wherein
the doping concentration of the anode region is lower than the doping concentration of the base region.

29. The semiconductor device according to claim 1, wherein
the semiconductor substrate is not provided with a lifetime control region including a lifetime killer in a front surface side compared to a center in a depth direction of the semiconductor substrate.
